(19) United States
(12) Patent Application Publication
(10) Pub. No.: US 2006/0128163 A1
(43) Pub. Date: Jun. 15, 2006

(54) SURFACE TREATMENT OF POST-RIE-DAMAGED P-OSG AND OTHER DAMAGED MATERIALS

(75) Inventors: Shyng-Tsong Chen, Patterson, NY (US); Kaushik Arun Kumar, Beacon, NY (US); Kelly Malone, Poughkeepsie, NY (US)

Correspondence Address: WHITHAM, CURTIS & CHRISTOFFERSON, P.C., 11491 SUNSET HILLS ROAD, SUITE 340, RESTON, VA, 20190, US

(73) Assignee: International Business Machines Corporation, Armonk, NY (US)

(21) Appl. No.: 10/905,065

(22) Filed: Dec. 14, 2004

(51) Int. Cl. H01L 21/469

(52) U.S. Cl. 438/780; 438/782; 438/790

(57) ABSTRACT

Damaged porous OSG layers and other damage may be chemically healed. Chemical healing is particularly advantageous in a porous OSG layer in a sub 90 nm ILD. For example, chemical healing may be by reacting the damage with an adhesion promoter having a “k” value comparable to the “k” value desired in the damaged material. Damaged porous OSG layers (which are hydrophilic) may be manipulated to prevent them from allowing moisture to reach copper lines. Undesirable copper out-diffusion can be controlled in ILDs having porous OSG geometry.

### FIELD OF THE INVENTION

The present invention generally relates to semiconductor device manufacturing, and, more particularly, to interlevel devices (ILDs).

### BACKGROUND

Copper (Cu) is commonly used as a conductive material in a number of microelectronic devices, such as for chip wiring, packaging structures, integrated circuits, etc. (e.g., US 2001/0019884 A1 to Miller et al. (published Sep. 6, 2001); U.S. Pat. No. 6,583,047 to Daniels et al. (patented Jun. 24, 2003)), and, specifically, in copper lines in interlevel dielectrics (ILDs). E.g., U.S. Pat. No. 6,586,334 to Jiang (patented Jul. 1, 2003); U.S. Pat. No. 6,566,283 to Pangrie et al. (patented May 20, 2003).

In working with ILDs, it generally has been preferred in most applications to use dielectric materials with low dielectric constant, k. With sub 90 nm technology development, ILDs having ultra low-k (ULK) have been demanded to meet resistance-capacitance (RC) delay and performance requirements. However, with most ULK materials, the addition of porosity is often required to reach k values below 2.6. Organic low-k and ULK materials often suffer from high coefficient of thermal expansion (CTE) values, which can lead to thermal cycle failures through CTE mismatches with copper metal. Therefore, the use of porous organic doped silsequioxane or silica glass (OSG) materials for ULK interlevel dielectrics has emerged as an attractive industry alternative. These materials are Si—O—R-based, and can be processed with similar chemistry as dense Si-based materials. “R” denotes hydrogen, or an aliphatic species (CxHy).

However, a drawback of the above-mentioned OSG materials (especially the porous OSG materials) is plasma damage during resist stripping. Typical conventional strip chemistries have lead to carbon depletion layers in the OSG films. This problem of damage during plasma processing is worse for porous OSG materials because these materials are less dense than the non-porous OSG ILDs. (An example of a damaged layer 10 is shown in FIG. 1.) With the reduction in density and increased porosity, damaging radicals are able to permeate deeper into the bulk of the ILD film. With smaller dimensions between copper lines, there is an even greater impact of the damage layer on the reliability of the integrated structure. This impact is seen in the increase of hydrophilicity of the film, increased line-to-line capacitance, and poor barrier adhesion.

Conventionally, a wet clean process has been used to remove some damaged OSG layers (such as a damaged layer 10 in FIG. 1). However, such an attempted solution has not been found to be satisfactory when the damaged layer is within a porous dielectric.

### SUMMARY OF THE INVENTION

In the invention, the above-mentioned problems are addressed for a damaged material (especially a damaged porous material such as a carbon-depleted p-OSG layer) by a process of chemically healing the damaged material by applying (such as by coating in liquid form) an adhesion promoter having a “k” value comparable to the “k” value desired in the damaged material. The “k” value of a material is its dielectric constant, and is a property commonly-referenced and/or measured when working with semiconductor materials.

In the invention, advantageously, hydrophilic properties of porous OSG layers may be manipulated and controlled, such as manipulating damaged porous OSG layers (which are hydrophilic) to prevent such damaged layers from allowing moisture to reach copper lines, thereby preventing contribution to undesirable copper out-diffusion. The invention thus advantageously provides improved copper/liner reliability.

The invention also provides for a strategic avoidance of moisture reaching copper lines in certain devices (such as ILDs, especially ILDs comprising copper lines), and a strategic avoidance of copper out-diffusion.

The invention in a preferred embodiment pertaining to a semiconductor device provides a method of repairing a damaged layer (such as, e.g., a damaged layer that was formed by RIE-damage and/or photoresist strip damage; an organic doped silsesquioxane or silica glass (OSG) layer (such as, preferably, a porous OSG); a layer including unreacted O—Si groups and OH—Si groups; a layer that is carbon-depleted; a material having dielectric constant k in a range of about 2.4 to 2.7; and other porous and non-porous damaged layers), comprising the steps of: contacting the damaged layer having dangling O⁻ bonds (optionally being present as —OH) with a chemical healing agent (such as, e.g., a prepolymer solution that reacts to form an oligomer in the presence of the dangling O⁻ bond or OH group; a compound that comprises Si—O—R (wherein “R” is hydrogen or an aliphatic species CₓH_{y} where x and y may be the same or different, x is positive, and y may be 0 or positive); a phenyl-vinyl-hydrido silsesquioxane; a compound comprising Si—O—R′ groups (where R′ may be the same or different and is selected from phenyl (C₆H₅) groups, vinyl (CH═CH) groups, and hydrido (—H)); a material having a dielectric constant k equal to or approximately equal to the dielectric constant k of the damaged layer; a material having dielectric constant k in a range of about 2.4 to 2.7; and other chemical healing agents); and reacting the damaged layer and the chemical healing agent until a chemically-healed layer is formed, such as, for example, until a chemically-healed layer having a thickness of about 10 to 100 Angstroms is formed; etc. Without the invention being limited thereto, some examples of such inventive methods are, e.g., a method including conformally spinning-on an adhesion promoter; a method including heating the damaged layer in the presence of the chemical healing agent; a method including furnace curing of the damaged layer in the presence of the chemical healing agent, wherein a cross-linked polymer is formed; a method including hot plate baking the damaged layer in the presence of the chemical healing agent, wherein an oligomer is formed; a method wherein the damaged layer includes Si—O₋ and Si—OH, and unreacted O₋ or OH of the damaged layer reacts with the chemical healing agent; a method wherein the chemically-healed layer is formed from the damaged layer in a time in a range of about 2 to 10 minutes, under atmospheric pressure, at a temperature in a range of about 250°-450° C.; a method including coating an adhesion promoter (AP) material having a thickness in a range of about 10 to 100 Angstroms; a method including a chemical reaction of an adhesion promoter with the damaged layer; a method including conformally spinning-on an adhesion promoter followed by argon sputtering; etc.

In another preferred embodiment, the invention provides a method of making a device (such as a sub 90 nm device and other devices) including at least one conductive metal (such as, e.g., copper, copper alloys, aluminum, aluminum alloys, titanium, tantalum, tungsten, etc., most preferably, copper) region, comprising at least the steps of: (a) chemically healing a damaged OSG layer (such as a porous or non-porous OSG layer, preferably, a porous OSG layer) to provide a healed OSG layer; (b) forming in the device at least one conductive metal region; such as, e.g., a method wherein the healed OSG layer is formed from the damaged OSG layer in a range of about 2-10 minutes; a method wherein the healing step is performed after reactive ion etching (RIE) and includes coating an adhesion promoter (AP) having a dielectric constant k in a range of about 2.4 to 2.7; a method wherein the healing step is performed under atmospheric pressure at a temperature in a range of about 250° to 450° C.; a method wherein the healed OSG layer is in a vicinity immediately adjacent to the metal region; a method wherein the metal region forming may be before or after the healing step; a method wherein the OSG is porous-OSG (p-OSG); a method further including a step of liner deposition after the healing; a method including a plating step (such as copper plating) after liner deposition; a method wherein the healing step includes a conformal, spin-on adhesion promoter being chemically reacted with the damaged organosilicate glass (OSG) layer; etc.

In a further preferred embodiment, the invention provides a process for preventing copper out-diffusion from a copper line in an interlevel device (such as, e.g., a sub 90 nm device, and other devices), comprising: chemically reacting an adhesion promoter (AP) with an RIE-/strip-damage layer wherein a chemically-healed layer is formed, the chemically-healed layer and the copper line being situated with the chemically-healed layer preventing copper out-diffusion, such as, e.g., a process including coating the AP onto an RIE-damaged layer, etc.

Another preferred embodiment of the invention provides a copper-line containing device, comprising: an adhesion promoter material (AP) chemically reacted to a layer having a dielectric constant k in a range of about 2.4 to 2.7, and a copper line, wherein copper in the device is not out-diffusing, such as, e.g., a device including a porous material; a sub 90 nm device; an interlevel device (ILD); etc.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 shows a cross-sectional diagram of post RIE plasma damage.

FIGS. 2A-C are cross-sectional diagrams showing a process embodiment according to the invention. In FIG. 1A, chemical healing is performed according to an embodiment of the invention, resulting in the chemically-healed structure of FIG. 1B. In FIG. 1C, a liner/plate/CMP product according to the invention is shown.

### DETAILED DESCRIPTION OF A PREFERRED EMBODIMENT

The present invention provides for chemically healing part of a dielectric layer, namely, a carbon-depleted damaged region that has dangling O⁻ bonds (optionally being present as —OH). Such a damaged region may be treated with a chemical healing agent (preferably similar in k value to the dielectric region), whereby the chemical healing agent reacts with dangling O— bonds to form a healed region preferably with k value the same, or about the same, as the dielectric region. The k value is preferably the same but is not required in all embodiments to be the same. The invention preferably may be used for healing an OSG layer damaged from having undergone reactive ion etching (RIE) and/or photoresist strip (especially, e.g., during an ILD manufacturing process), but the inventive repairing is not limited to layers so damaged.

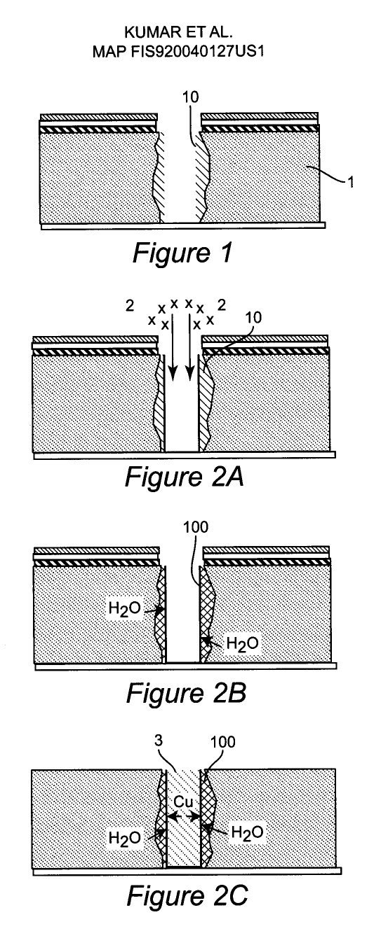

The present invention in a preferred embodiment may be appreciated with regard to FIGS. 1, 2A-C. FIG. 1 shows a step in a process of forming an interlevel device (ILD), after reactive ion etching (RIE) has been performed and/or a plasma step has been performed, resulting in part of the dielectric 1 being damaged regions 10. Damaged regions 10 are carbon-depleted and have dangling O⁻ bonds (optionally being present as —OH). That is, the damaged regions 10 have dangling oxygen bonds that are rapidly hydrolyzing between the forms R—Si—O⁻ and R—Si—OH. “R” groups are understood to be carbon-containing. When the damaged region 10 is included in an interlevel device (ILD) film, the dangling O⁻ bonds may be present throughout the thickness of the ILD film, or the dangling O⁻ bonds may be present in a part of the thickness of the ILD film.

For an ILD application, a damaged region 10 cannot be permitted to remain as is because the desired functioning of the ILD could not be obtained. The damaged region 10 will have unpaired electrons from Si—O— linkages created by the removal of —R groups during plasma processing for example etch or photoresist strip. These Si—O groups are very hydrophilic, which is an undesirable feature if copper is to be provided in the immediate vicinity.

In the case where the damaged region 10 is included in a dielectric material 1 which is non-porous, there conventionally has been applied an approach of removing the damaged layer 10, such as through a wet cleans process.

However, in the case where the dielectric material 1 and its damaged region 10 are porous, such an approach of removing the damaged region 10 to date has not been feasible, because there has not been known any way to avoid removing too much of the damaged region 10. Also there has not been known how to prevent the wet clean material from permeating the ILD and being trapped therein or from doing undesirable etching. When patterned porous OSG films are etched, they undergo plasma damage to some degree (rendering the structure not useable for making an ILD), and when these damage layers have been removed, large, off-target critical dimensions (CDs) have been generated, rendering the device not meeting capacitance targets for the given technology.

However, the present invention advantageously provides that a damaged region 10 (FIGS. 1, 2A) be repaired, such as, for example, reacting the damaged region 10 with a chemical healing agent 2 (FIG. 2A).

An example of the chemical healing agent 2 is an adhesion promoter material, such as, for example, polymeric materials comprising R—Si—O—Rₓ, where R is H, or an aliphatic C_{y}H_{z} functional group (such as, e.g., methyl silsesquioxanes, phenyl silsesquioxanes, MSQs, HOSP™, Ensemble™, or any other organo silsesquioxane, etc.), etc. Examples of adhesion promoters for use in the invention are adhesion promoter (AP) materials with similar chemistries, and k values of the dielectric material 1 (such as a pOSG material, etc.), materials whose addition to the integration scheme will not impact the overall device performance, etc. A preferred example of AP materials are AP materials that planarize conformally over defined trenches and vias, for single damascene processing or dual damascene processing.

Regarding manner of application of chemical healing agent 2 to the damaged region 10, preferably the chemical healing agent is applied in a liquid form. Preferably the healing agent 2 is applied in liquid form, with the healing agent 2 maximally conforming to the surface geography of the damaged region, optionally including spin coating or dipping.

An example of the amount in which a liquid chemical healing agent is applied is, e.g., a thickness range between about 10 and 100 Angstoms, preferably about 80 Angstroms. Preferably the healing agent coats the patterned features conformally. The chemical healing agent 2 may be applied non-stoichiometrically. The chemical healing agent 2 may be applied in an amount so that some or all of the chemical healing agent 2 reacts with the damaged region 10, or the chemical healing agent 2 may be applied in excess. When the chemical healing agent 2 is applied in excess, the excess may remain in place when further process steps (such as, e.g., liner deposition, copper plating, etc.) are performed. Most preferably, the chemical healing agent 2 is applied in sufficient amount to perform maximal healing of damaged region 10.

While the example of a chemical healing agent that is a liquid has been given, the healing agent 2 is not prohibited from another form, such as, e.g., a gaseous healing agent.

Returning to FIGS. 2A-2B, when chemical healing agent 2 is applied to the damaged region 10 as the invention provides, chemical healing agent 2 reacts with damaged region 10 and repairs the damaged region 10 into healed region 100 (FIG. 2B). For example, where damaged region 10 is an area of a porous OSG (p-OSG) film that was damaged by reactive ion etching, the damaged region 10 may be encapsulated using as a healing agent 2 silicon-based adhesion promoters applied in a spin-on process.

The healing agent 2 is applied under conditions permitting reaction of healing agent 2 and the damaged regions 10. For example, when an adhesion promoter is used as the healing agent 2 and is spun on a wafer, after the AP is spun on the wafer, the wafer may be baked under conditions to drive off solvents and/or to partially crosslink the AP material (such as at a baking temperature in a range of about 100-400° C., preferably 310° C., for times ranging from 30 seconds to 5 minutes, preferably 1 minute), and/or at a temperature and for a time such that the heat from baking the healing agent (such as the AP) initiates a reaction with the damaged layer (such as the damaged OSG layer), thereby “healing” the damage.

Whether a damaged region 10 has been healed may be determined, for example, by a measurement, such as by, e.g., electron energy loss spectroscopy (EELS), a transmission electron microscopy (TEM), etc. For example, a damaged layer will have higher leakage and capacitance. When healing occurs, measured leakage and/or capacitance may decrease, distinguishing a healed region 100 (FIGS. 2B, 2C) from a damaged region 10 (FIGS. 1, 2A). Examples of properties that may be measured for determining whether healing has occurred are, e.g., contact angle, k value, etc. For example, measurement of contact angle and/or of k value may be used to establish that dangling O⁻ bonds and OH groups have been converted. Thus, TEM/EELS analysis or capacitance measurement may be used to confirm that a damaged layer has been converted into a healed layer.

A healed region 100 is not required to be completely restored to the original condition of the dielectric 1 and that complete healing is not believed to be possible in most cases. Namely, there may usually be a depth beyond which healing cannot be effected. The depth to which healing occurs may be a function of pore size, material density, etc. Thus, a healed region 100 may (but is not required to) include unrepaired, still-damaged areas.

Referring to a damaged region such as damaged region 10 in FIG. 1, the damaged layers 10 will have unpaired electrons from Si—O-linkages created by the removal of —R groups during the etch. These Si—O groups are very hydrophilic. Therefore, if a copper line were deposited in the region between damaged regions 10 in FIG. 1, moisture from damaged regions 10 undesirably would reach the copper lines and undesirable out-diffusion of copper would occur. Moisture can undesirably increase capacitance between lines, and it is wanted to prevent moisture from having such effect in an ILD.

In cases where plasma damage is unavoidable, this invention provides a way (such as, for example, by the process mentioned above and described with regard to FIGS. 2A-2C) to prevent moisture from reaching a copper line.

Referring to FIGS. 2B-2C, a conductive metal line 3 (such as copper, copper alloys, aluminum, aluminum alloys, titanium, tantalum, tungsten, etc., most preferably, copper) is deposited or plated in the opening defined by healed regions 100, the line 3 (such as a copper line) is relatively more protected from water reaching the line 3 than if the line had been deposited in the opening defined by damaged regions 10. In FIG. 2C, it will be appreciated that Cu is shown by way of example for line 3, and that the line 3 may be another conductive metal. As seen on FIG. 2C, in the invention moisture (H₂O) associated with the healed region 100 is contained and prevented from affecting the line 3.

Thus, the present invention can be used to protect lines 3 (such as copper lines) from moisture diffusion from pOSG ILDs.

In FIGS. 2B and 2C, moisture (H₂O) is shown for indicating where it is likely to occur, but it will be appreciated that moisture is undesirable and is not required to be present and is not sought to be introduced. The moisture (H₂O) shown on FIGS. 2B and 2C represents unavoidable moisture, if any.

It will be appreciated that (referring to FIGS. 2B-2C), prior to a line 3 (such as a copper line) being constructed, a step of depositing a liner may be performed.

An additional advantage of the application of the healing agent 2 (such as the adhesion promoter) to a damaged region 10 may be to provide a healed region 100 having a relatively smoother surface than the damaged region 10 for receiving subsequent liner deposition, and copper plating, thereby alleviating incomplete liner/copper voiding issues.

In FIGS. 1 and 2A-C, the invention has been discussed with regard to damaged regions 10 that are sidewalls. The present invention is particularly preferred for repairing a damaged region that is a sidewall. However, it should be appreciated that chemical healing according to the present invention may be applied in various geometries and is not limited to cases where a damaged region is a sidewall.

The Examples set forth below are illustrative, and the invention is not limited thereto.

### EXAMPLE 1

In this inventive Example, OSG ILD films are deposited on a substrate and cured to generate porosity. The ILD films can be deposited, for example, by a spin-apply or a CVD method. These films can have, for example, a templated or porogen-based chemistry. In either case, upon the cure of the film, an increase in free volume is generated in the form of pores. These films can be cured by thermal methods, or with irradiation (eBeam, ultraviolet, etc.) for about 2-10 minutes, with an optimal time of about 3-5 minutes. The cure temperature may be in a range from about 250° C.-450° C., with optimal cure temperatures between about 350° C.-400° C. Additional films are deposited on the porous OSG ILD film, and patterned through a lithographic process. The exposed film stack is then patterned by reactive ion etching (RIE), and the remaining photoresist is stripped. During exposure to these plasma processes, the porous OSG ILD film undergoes plasma damage. Thus, a damaged p-OSG ILD film has been constructed.

### EXAMPLE 2

To the damaged p-OSG ILD films of Example 1, after RIE/strip, adhesion promoter (AP) material is spin-applied on the wafer, and fills the patterned features. Examples of the adhesion promoter material are, e.g., methyl silsesquioxanes, phenyl silsesquioxanes, MSQs, HOSP™, Ensemble™, or any other organo silsesquioxane, etc. The mentioned adhesion promoter materials in this Example are polymeric materials with R—Si—O—Rₓ, where R is H, or an aliphatic C_{y}H_{z} functional group.

The AP has a thickness range between 10 and 100 A, preferably 80 A, and coats the patterned features conformally.

After the AP is spun on the wafer, the wafer is baked to drive off solvents, and to partially crosslink the AP material. The baking temperature ranges from 100°-400° C., preferably 310° C., for times ranging from 30 sec-5 minutes, preferably 1 min. During this time, the heat from baking the AP initiates a reaction with the damaged OSG layer, thereby “healing” the damage.

Thus, in cases where plasma damage is unavoidable, this invention offers a pathway to prevent moisture from interacting with a subsequent metallization layer.

### EXAMPLE 3

As the adhesion promoter may be used a polymer that begins to form an oligomer when heated (hot-plate baked), and forms a fully cross-linked polymer upon furnace curing. The hotplate baked film has similar properties to that of the fully crosslinked film in terms of etch rate etc., which indicates that the hotplate bake actually pushes the reaction of the AP.

The polymer is a phenyl-vinyl-hydrido silsesquioxane, which means that it has the basic Si—O—R functionality, with the R groups composed of phenyl (C₆H₅), vinyl (CH═CH), and hydrido (—H) groups.

Any of the functional groups can react with the damaged polymer, which will be hydrophilic, and contain unreacted ⁻O—Si groups.

Therefore, the basic reaction will be as follows:
Polymer-Si(OR)ₓ—O⁻ (H)+R₁—O—(OR)ₓ—Si-AP→Polymer-Si(OR)ₓ+₁—O—(OR)ₓSi-AP
where the Polymer-Si(OR)ₓ—O⁻ (H) is the damaged ILD material with a dangling bond generated from plasma damage, and R₁—O—(OR)ₓ—Si-AP is the AP showing the reactive functional group. The AP in this case has either cage or network structure.

### EXAMPLE 4

Post-etch, an Si—O—R based adhesion promoter was spun on, to react with and seal damaged ILD materials. The adhesion promoter was spun on conformally, with a slight amount of puddling observed at the bottom of the line or via. The puddling can be removed using argon sputter.

### EXAMPLE 5

In a sub-90 nm ILD with copper lines, conventional rinsing of a damaged porous dielectric would not be feasible because a considerable amount of the dielectric material would be etched away. By contrast, according to the invention, the damaged porous region may be chemically healed.

While the invention has been described in terms of its preferred embodiment, those skilled in the art will recognize that the invention can be practiced with modification within the spirit and scope of the appended claims.

What is claimed is:

1. A method of repairing a damaged layer in a semiconductor device, comprising:
contacting a damaged layer having dangling O— bonds (optionally being present as —OH) with a chemical healing agent; and
reacting the damaged layer and the chemical healing agent until a chemically-healed layer is formed.

2. The method of claim 1, wherein the chemically-healed layer has a thickness of about 10 to 100 Angstroms.

3. The method of claim 1, including conformally spinning-on an adhesion promoter.

4. The method of claim 1, wherein the chemical healing agent is a prepolymer solution that reacts to form an oligomer in the presence of the dangling O⁻ bond or OH group.

5. The method of claim 1, including heating the damaged layer in the presence of the chemical healing agent.

6. The method of claim 1, including at least one of: (A) furnace curing of the damaged layer in the presence of the chemical healing agent, wherein a cross-linked polymer is formed; (B) hot plate baking the damaged layer in the presence of the chemical healing agent, wherein an oligomer is formed.

7. The method of claim 1, wherein the chemical healing agent includes Si—O—R groups and the damaged layer includes unreacted O—Si groups and OH—Si groups.

8. The method of claim 1, wherein the damaged layer is carbon-depleted.

9. The method of claim 1, wherein the damaged layer includes Si—O— and Si—OH, and unreacted O⁻ or OH of the damaged layer reacts with the chemical healing agent.

10. The method of claim 1, wherein the chemical healing agent is a phenyl-vinyl-hydrido silsesquioxane.

11. The method of claim 1, wherein the chemical healing agent comprises Si—O—R′ groups, where R′ may be the same or different and is selected from phenyl (C₆H₅) groups, vinyl (CH═CH) groups and hydrido (—H).

12. The method of claim 1, wherein the chemical healing agent comprises Si—O—R, wherein “R” is hydrogen or an aliphatic species (CₓH_{y} where x and y may be the same or different, x is positive, and y may be 0 or positive).

13. The method of claim 1, wherein the damaged layer is an organic doped silsesquioxane or silica glass (OSG) layer.

14. The method of claim 1, wherein the damaged layer is a porous OSG.

15. The method of claim 1, wherein the chemical healing agent has a dielectric constant k equal to or approximately equal to the dielectric constant k of the damaged layer.

16. The method of claim 1, wherein the chemical healing agent and the damaged layer have dielectric constants k in a range of about 2.4 to 2.7.

17. The method of claim 1, wherein the chemically-healed layer is formed from the damaged layer in a time in a range of about 2 to 10 minutes, under atmospheric pressure, at a temperature in a range of about 250°-450° C.

18. The method of claim 1, including a chemical reaction of an adhesion promoter with the damaged layer.

19. The method of claim 1, wherein measurement of contact angle and/or of k value establishes that dangling O⁻ bonds and OH groups have been converted.

20. The method of claim 1, wherein transmission electron microscopy (TEM)/electron energy loss spectroscopy (EELS) analysis or capacitance measurement confirms that the damaged layer has been converted into a healed layer.

21. The method of claim 1, wherein the damaged layer is included in an interlevel device (ILD) film, wherein the dangling O⁻ bonds are present throughout the thickness of the ILD film or are present in a part of the thickness of the ILD film.

22. A method of making a device including at least one conductive metal region, comprising at least the steps of:
(a) chemically healing a damaged OSG layer to provide a healed OSG layer;
(b) forming in the device at least one conductive metal region.

23. The method of claim 22, wherein the metal is selected from the group consisting of copper, copper alloys, aluminum, aluminum alloys, titanium, tantalum and tungsten.

24. The method of claim 22, wherein the damaged OSG is porous.

25. The method of claim 22, wherein the healing step is performed after reactive ion etching (RIE) and includes coating an adhesion promoter (AP) having a dielectric constant k in a range of about 2.4 to 2.7.

26. The method of claim 25, wherein the coated AP has a thickness in a range of about 10 to 100 Angstroms.

27. The method of claim 22, wherein the healed OSG layer is in a vicinity immediately adjacent to the metal region.

28. The method of claim 22, further including a step of liner deposition after the healing.

29. The method of claim 28, including a step of copper plating after the liner deposition.

30. The method of claim 22, wherein the healing step includes a conformal, spin-on adhesion promoter being chemically reacted with the damaged organosilicate glass (OSG) layer.
